(19) United States
(12) Patent Application Publication
(10) Pub. No.: US 2022/0092237 A1
(43) Pub. Date: Mar. 24, 2022

(54) METHOD AND DEVICE FOR PROCESSING DATA ASSOCIATED WITH A SIMULATION MODEL FOR AT LEAST ONE ASPECT OF A TECHNICAL SYSTEM

(71) Applicant: Robert Bosch GmbH, Stuttgart (DE)

(72) Inventors: Antoine Vandamme, Gerlingen (DE); Michael Schick, Karlsruhe (DE); Philipp Glaser, Stuttgart (DE); Wolfgang Ulmer, Rutesheim (DE)

(21) Appl. No.: 17/477,952

(22) Filed: Sep. 17, 2021

(30) Foreign Application Priority Data
Sep. 24, 2020 (DE) 10 2020 211 992.9

(51) Int. Cl. G06F 30/20

(52) U.S. Cl. CPC G06F 30/20

(57) ABSTRACT

A computer-implemented method for processing data associated with a simulation model, the simulation model being designed to simulate at least one aspect of a technical system. The method includes: ascertaining a first parameter group of parameters of the simulation model, whose sensitivity exceeds a predefinable sensitivity limiting value, ascertaining a substitute model for the simulation model based on the first parameter group, assessing a quality of the substitute model, a quality measure characterizing the quality of the substitute model being obtained.

### FIELD

The present invention relates to a method for processing data associated with a simulation model.

The present invention also relates to a device for processing data associated with a simulation model.

### SUMMARY

Exemplary specific embodiments of the present invention relate to a method, for example, to a computer-implemented method, for processing data associated with a simulation model, the simulation model being designed to simulate at least one aspect of a technical system, the method including: ascertaining a first parameter group of parameters of the simulation model, whose sensitivity exceeds a predefinable sensitivity limiting value, ascertaining a substitute model for the simulation model based on the first parameter group, assessing a quality of the substitute model, a quality measure characterizing the quality of the substitute model being obtained. This enables a substitute model to be provided, which in further exemplary specific embodiments may, for example, be more efficiently evaluated than the simulation model itself.

In further exemplary specific embodiments of the present invention, the predefinable sensitivity limiting value may be ascertained, for example, based on a total number of parameters of the simulation model, for example, in such a way that the number of parameters of the first parameter group forms a predefinable portion with respect to the total number of parameters.

In further exemplary specific embodiments of the present invention, at least one of the following elements is used as a substitute model: a) chaos polynomials, b) Gaussian processes, c) for example, artificial neural networks.

In further exemplary specific embodiments of the present invention, the substitute model is trained in such a way that it exhibits a predefinable, for example, sufficiently high, quality as compared to the—in further exemplary specific embodiments, potentially far more computationally intensive—simulation model (“original model”).

In further exemplary specific embodiments of the present invention, it is provided that the technical system includes at least one of the following elements: a) hardware, b) software, c) a combination of hardware and software, for example, an embedded system including a microcontroller, which is able to execute a computer program.

In further exemplary specific embodiments of the present invention, it is provided that the hardware includes at least one of the following elements: a) sensor, b) actuator, c) hardware circuitry, d) electrical and/or electronic and/or electromechanical component, e) electric machine, for example, rotating electric machine, for example, electric motor, f) computing device, for example, microprocessor and/or microcontroller and/or embedded system.

In further exemplary specific embodiments of the present invention, the hardware includes, for example, a power hand tool such as, for example, a drill hammer, or an electric drive, for example, for a power window or a windshield wiper, for example, of a motor vehicle.

In further exemplary specific embodiments of the present invention, the above-described combination of hardware and software may, for example, also be formed by a vehicle, for example, a motor vehicle, by means of which in further exemplary specific embodiments a simulation of the entire vehicle (“total vehicle simulation”), for example, is implementable with the aid of the simulation model or of the substitute model.

In further exemplary specific embodiments of the present invention, it is provided that the software includes at least one of the following elements: a) a computer program for operating or for an activation of a hardware, for example, at least of one of elements a) through f), b) a computer program for simulating at least one component of the technical system, for example, for simulating an operation of the at least one component, c) an operating system for a computing device, for example, of an embedded system.

In further exemplary specific embodiments of the present invention, it is provided that the simulation model is designed for at least one of the following elements: a) simulation, for example, a computer-implemented simulation of the technical system, b) simulation, for example, a computer-implemented simulation for researching and/or developing the technical system, c) simulation, for example, a computer-implemented simulation, for discovering errors of the technical system or in the technical system or errors, which are related to the technical system, for example, which may be caused by the technical system, d) simulation for validating and/or verifying a safety, for example, a functional safety of the technical system.

In further exemplary specific embodiments of the present invention, it is provided that the method further includes: for example, based on the simulation, a) varying at least one parameter, which may influence the technical system and/or the simulation model, b) eliminating errors, c) enabling the technical system.

In further exemplary specific embodiments of the present invention, it is provided that the method further includes: carrying out a sensitivity analysis, for example, based on a predefinable number of, for example, already present simulation evaluations of the simulation model and, optionally, ascertaining the first parameter group based on the sensitivity analysis, the first parameter group, for example, including at least one parameter.

In further exemplary specific embodiments of the present invention, it is provided that the method further includes: ascertaining a second parameter group of parameters of the simulation model, whose sensitivity does not exceed the predefinable sensitivity limiting value and, optionally, fixing the parameters of the second parameter group, for example, at a predefinable, for example, nominal value.

In further exemplary specific embodiments of the present invention, it is provided that the ascertainment of the substitute model for the simulation model includes: simplifying the simulation model based on a, for example, targeted, evaluation of the simulation model via setpoints in a parameter space, for example, characterizable by the first parameter group. In further exemplary specific embodiments of the present invention, “targeted” is understood to mean: the characteristics of parameter space GP1 associated with the first parameter group, for example, are utilized or exploited. In order to train the substitute model, for example, only few representative simulation points are evaluated. In further exemplary specific embodiments, these may be, for example, limiting values (for example, upper and lower barriers) and/or statistical moments (for example, mean values) and/or expert points.

In further exemplary specific embodiments of the present invention, it is provided that the assessment of the quality of the substitute model is carried out based on a or on the predefinable number of, for example, already present, simulation evaluations of the simulation model.

In further exemplary specific embodiments of the present invention, it is provided that the method further includes: ascertaining, for example, identifying, a third parameter group, whose parameters influence a quality of the assessment of the quality of the substitute model and, optionally, expanding the substitute model based on at least one parameter of the third parameter group, for example, based on at least one evaluation of the simulation model for the at least one parameter of the third parameter group.

In further exemplary specific embodiments of the present invention, it is provided that the method further includes: repeating at least one of the following steps, for example, until a predefinable abort criterion is met: a) assessing the quality of the substitute model, b) ascertaining the third parameter group, c) expanding the substitute model based on at least one parameter of the third parameter group, the predefinable abort criterion including at least one of the following elements: a) a change of a value of the quality measure falls below a predefinable threshold value, b) a setpoint value for the quality measure is achieved.

In further exemplary specific embodiments of the present invention, it is provided that at least some, preferably all, steps are automated, i.e., are carried out without the interaction with a person.

In further exemplary specific embodiments of the present invention, it is provided that the ascertainment of the substitute model for the simulation model includes: at least temporarily storing parameters of the first parameter group and, for example, assigning to a first hierarchical level (for example, comparable to a first iteration), carrying out a sensitivity analysis based on the first parameter group, ascertaining a modified first parameter group based on the sensitivity analysis, the modified first parameter group, for example, corresponding to a second hierarchical level (or iteration) and, optionally, repeating the steps of at least temporarily storing, of carrying out the sensitivity analysis, and of ascertaining and, optionally, incrementing the hierarchical level until a predefinable abort criterion is met, the predefinable abort criterion, for example, including a predefinable number of repetitions, for example, corresponding to an instantaneous value of the hierarchical level.

In further exemplary specific embodiments of the present invention, it is provided that the method further includes: carrying out at least one of the following steps based on the modified first parameter group of an instantaneous hierarchical level or repetition: a) simplifying the simulation model, b) assessing a quality of the substitute model, c) ascertaining, for example, identifying, the third parameter group, d) expanding the substitute model based on at least one parameter of the third parameter group, e) repeating at least one of the following steps, for example, until a predefinable abort criterion is met: aa) assessing the quality of the substitute model, bb) ascertaining the third parameter group, cc) expanding the substitute model based on at least one parameter of the third parameter group, the predefinable abort criterion including at least one of the following elements: a′) a change of a value of the quality measure falls below a predefinable threshold value, b′) a setpoint value for the quality measure is achieved.

In further exemplary specific embodiments of the present invention, it is provided that the method further includes: switching to a preceding higher hierarchical level and, optionally, repeating the steps of carrying out and of switching to a preceding higher hierarchical level, for example, based on pieces of information or data or results of at least one lower hierarchical level.

Further exemplary specific embodiments of the present invention relate to a device for carrying out the method according to the specific embodiments.

Further exemplary specific embodiments of the present invention relate to a computer-readable memory medium, including commands which, when executed by a computer, prompt the computer to carry out the method according to the specific embodiments.

Further exemplary specific embodiments of the present invention relate to a computer program, including commands which, when the program is executed by a computer, prompt the computer to carry out the method according to the specific embodiments.

Further exemplary specific embodiments of the present invention relate to a data medium signal, which transmits and/or characterizes the computer program according to the specific embodiments.

Further exemplary specific embodiments of the present invention relate to a use of the method according to the specific embodiments and/or of the device according to the specific embodiments and/or of the computer-readable memory medium according to the specific embodiments and/or of the computer program according to the specific embodiments and/or of the data medium signal according to the specific embodiments for at least one of the following elements: a) ascertaining a substitute model for the simulation model simplified (for example, including fewer computing resources or less power) compared to the simulation model, b) automation of work steps for assessing the quality of a or of the substitute model, c) accelerating a quality ascertainment in simulation models, for example, by using the substitute model, d) quality enhancement of a quality assessment for a substitute model, for example, due to on an evaluation of the substitute model in parameter regions not previously considered, e) enabling, for example, improved and/or timely prognoses of quality characteristics of a product associated with or corresponding to the technical system, f) increasing a reliability in a production of a product associated with or corresponding to the technical system, g) increasing a product quality of a product associated with or corresponding to the technical system, h) shortening a development time of a product associated with or corresponding to the technical system.

Further features, possible applications and advantages of the present invention result from the following description of exemplary embodiments of the present invention, which are represented in the figures. All features described or represented, alone or in arbitrary combination, form the subject matter of the present invention, regardless of their wording or representation in the description or in the figures.

### BRIEF DESCRIPTION OF THE DRAWINGS

FIG. 1 schematically shows a simplified block diagram according to exemplary specific embodiments of the present invention.

FIG. 2 schematically shows a simplified block diagram according to further exemplary specific embodiments of the present invention.

FIG. 3 schematically shows a simplified block diagram according to further exemplary specific embodiments of the present invention.

FIG. 4A schematically shows a simplified block diagram according to further exemplary specific embodiments of the present invention.

FIG. 4B schematically shows a simplified block diagram according to further exemplary specific embodiments of the present invention.

FIG. 5 schematically shows a simplified flowchart according to further exemplary specific embodiments of the present invention.

FIG. 6 schematically shows a simplified flowchart according to further exemplary specific embodiments of the present invention.

FIG. 7 schematically shows a simplified flowchart according to further exemplary specific embodiments of the present invention.

FIG. 8 schematically shows a simplified flowchart according to further exemplary specific embodiments of the present invention.

FIG. 9 schematically shows a simplified flowchart according to further exemplary specific embodiments of the present invention.

FIG. 10 schematically shows a simplified block diagram according to further exemplary specific embodiments of the present invention.

FIG. 11 schematically shows aspects of uses according to further exemplary specific embodiments of the present invention.

### DETAILED DESCRIPTION OF EXAMPLE EMBODIMENTS

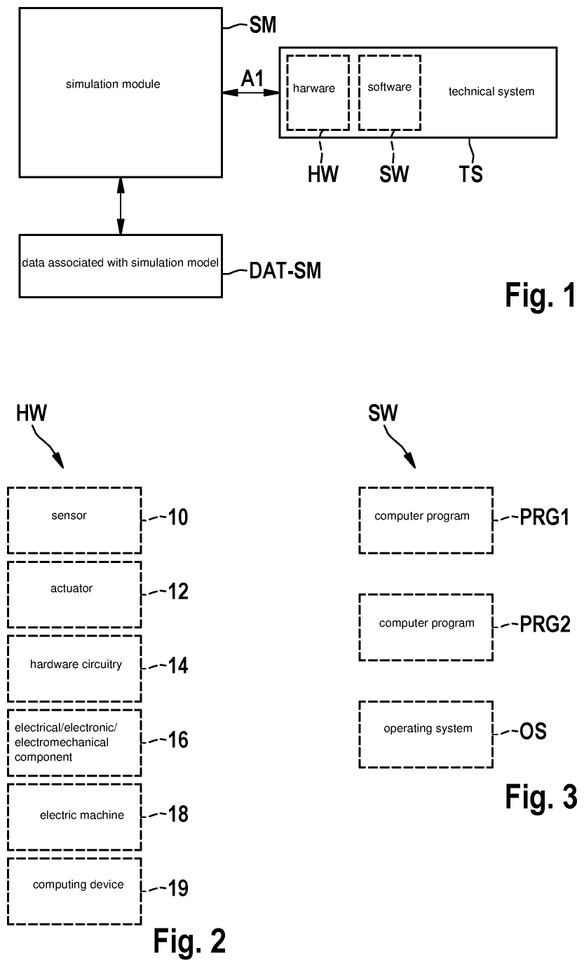

Exemplary specific embodiments, cf. FIG. 1 and FIG. 5, relate to a method, for example, to a computer-implemented method, for processing data DAT-SM associated with a simulation model SM (FIG. 1), the simulation model SM being designed to simulate at least one aspect of a technical system TS, cf. double arrow A1 according to FIG. 1. The method, FIG. 5, includes: ascertaining 100 a first parameter group GP1 of parameters of simulation model SM, whose sensitivity exceeds a predefinable sensitivity limiting value, ascertaining 102 a substitute model EM for simulation model SM based on first parameter group GP1, assessing 104 a quality of substitute model EM, a quality measure GM-EM characterizing the quality of substitute model EM being obtained. This allows a substitute model EM to be provided, which in further exemplary specific embodiments may, for example, be more efficiently evaluated than simulation model SM itself.

In further exemplary specific embodiments, the predefinable sensitivity limiting value may be ascertained, for example, based on a total number of parameters of simulation model SM, for example, in such a way that the number of parameters of the first parameter group GP1 forms a predefinable portion with respect to the total number of parameters.

In further exemplary specific embodiments, at least one of the following elements is used as substitute model EM: a) chaos polynomials, b) Gaussian processes, c) for example, artificial neural networks.

In further exemplary specific embodiments, substitute model EM is trained in such a way that it exhibits a predefinable, for example, sufficiently high, quality as compared to the—in further exemplary specific embodiments, potentially far more computationally intensive—simulation model SM (“original model”).

In further exemplary specific embodiments, it is provided that technical system TS, FIG. 1, includes at least one of the following elements: a) hardware HW, b) software SW, c) a combination of hardware HW and software SW, for example, an embedded system including a microcontroller, which is able to execute a computer program.

In further exemplary specific embodiments, FIG. 2, it is provided that hardware HW includes at least one of the following elements: a) sensor 10, b) actuator 12, c) hardware circuitry 14, (for example, discrete electronic circuitry), d) electrical and/or electronic and/or electromechanical component 16, e), electric machine 18, for example, rotating electric machine, for example, electric motor, f) computing device 19, for example, microprocessor and/or microcontroller and/or embedded system.

In further exemplary specific embodiments, hardware HW includes, for example, a power hand tool such as, for example, a drill hammer, or an electric drive, for example, for a power window or a windshield wiper, for example, of a motor vehicle.

In further exemplary embodiments, the above-described combination of hardware HW and software SW may, for example, also be formed by a vehicle, for example, a motor vehicle, by means of which in further exemplary specific embodiments a simulation of the entire vehicle (“total vehicle simulation”), for example, is implementable with the aid of the simulation model SM (FIG. 1) or of the substitute model EM (FIG. 5).

In further exemplary specific embodiments, FIG. 3, it is provided that software SW includes at least one of the following elements: a) a computer program PRG1 for operating or for an activation of a hardware HW, for example, of at least one of elements a) through f), b), cf. reference numerals 10 through 19 according to FIG. 2, b) a computer program PRG2 for simulating at least one component of technical system TS, for example, for simulating an operation of the at least one component, c) an operating system OS for a computing device, for example, of an embedded system.

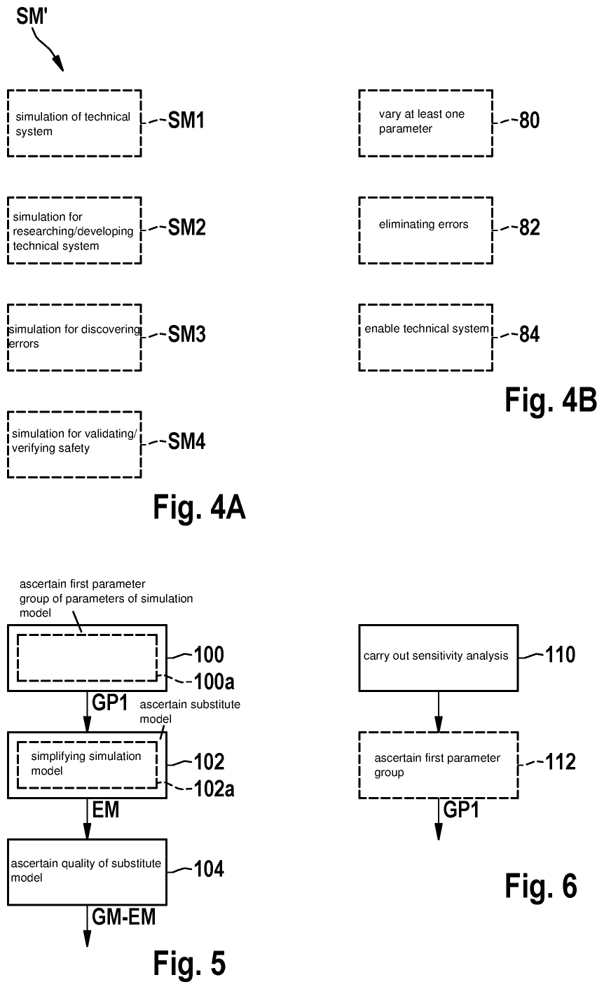

In further exemplary specific embodiments, FIG. 4A, it is provided that simulation model SM (FIG. 1) is designed for at least one of the following elements SM′: a) simulation SM1, for example, computer-implemented simulation, of technical system TS, b) simulation SM2, for example, computer-implemented simulation, for researching and/or developing technical system TS, c) simulation SM3, for example, computer-implemented simulation, for discovering errors of technical system TS or in technical system TS or errors, which are related to technical system TS, for example, which may be caused by technical system TS, d) simulation SM4 for validating and/or verifying a safety, for example, a functional safety of technical system TS.

In further exemplary specific embodiments, FIG. 4B, it is provided that the method further includes: for example, based on simulation SM1, SM2, SM3, SM4, a) varying 80 at least one parameter, which may influence technical system TS and/or simulation model SM, b) eliminating 82 errors, c) enabling 84 technical system TS.

In further exemplary specific embodiments, FIG. 6, it is provided that the method further includes: carrying out 110 a sensitivity analysis, for example, based on a predefinable number of, for example, already present simulation evaluations of simulation model SM and, optionally, ascertaining 112 first parameter group GP1 based on sensitivity analysis 110, first parameter group GP1, for example, including at least one parameter.

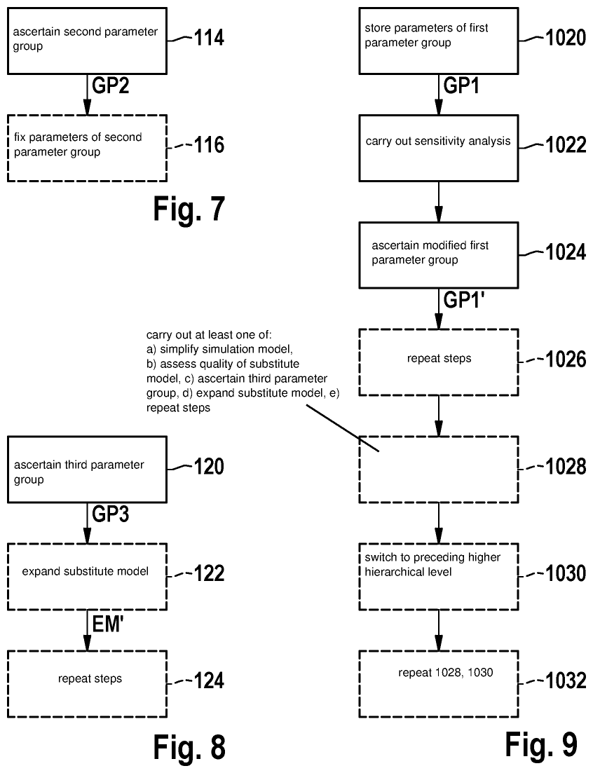

In further exemplary specific embodiments, FIG. 7, it is provided that the method further includes: ascertaining 114 a second parameter group GP2 of parameters of simulation model SM, whose sensitivity does not exceed the predefinable sensitivity limiting value (for example, “not (sufficiently) sensitive parameter”) and, optionally, fixing 116 (fixedly predefine) the parameters of second parameter group GP2, for example, at a predefinable, for example, nominal value.

In further exemplary specific embodiments, it is provided that ascertainment 102 (FIG. 5) of substitute model EM for simulation model SM includes: simplifying 102a simulation model SM based on a, for example, targeted, evaluation of simulation model SM via setpoints in a parameter space.

In further exemplary specific embodiments, it is provided that assessment 104 (FIG. 5) of the quality of substitute model EM is carried out based on a or on the predefinable number of, for example, already present, simulation evaluations of simulation model SM.

In further exemplary specific embodiments, FIG. 8, it is provided that the method further includes: ascertaining 120, for example, identifying, a third parameter group GP3, whose parameters influence a quality of the assessment of the quality of substitute model EM and, optionally, expanding 122 substitute model EM based on at least one parameter of third parameter group GP3, for example, based on at least one evaluation of simulation model SM for the at least one parameter of the third parameter group, for example, an expanded substitute model EM′ being obtained.

In further exemplary specific embodiments, FIG. 8, it is provided that the method further includes: repeating 124 at least one of the following steps, for example, until a predefinable abort criterion is met: a) assessing 104 the quality of substitute model EM, b) ascertaining 120 third parameter group GP3, c) expanding 122 substitute model EM (or potentially previously expanded substitute model EM′) based on at least one parameter of third parameter group GP3, the predefinable abort criterion including at least one of the following elements: a) a change of a value of quality measure GM-EM (for example, from a repetition 124 to another repetition 124) falls below a predefinable threshold value, b) a setpoint value for quality measure GM-EM is achieved.

In further exemplary specific embodiments, it is provided that at least some, preferably all, steps of the method according to the specific embodiments are automated, i.e., are carried out without the interaction with a person.

In further exemplary specific embodiments, FIG. 9, it is provided that ascertainment 102 (FIG. 5) of substitute model EM for simulation model SM includes: at least temporarily storing 1020 (FIG. 9) parameters of first parameter group GP1 and, for example, assigning to a first hierarchical level (for example, comparable to a first iteration), carrying out 1022 a sensitivity analysis (for example, similar to step 110 according to FIG. 6) based on first parameter group GP1, ascertaining 1024 a modified first parameter group GP1′ based on sensitivity analysis 1022, modified first parameter group GP1′, for example, corresponding to a second hierarchical level (or iteration) and, optionally, repeating 1026 the steps of the at least temporary storing 1020, of carrying out 1022 the sensitivity analysis, and of ascertaining 1024 and, optionally, incrementing the hierarchical level, until a predefinable abort criterion is met, the predefinable abort criterion, for example, including a predefinable number of repetitions 1026, for example, corresponding to an instantaneous value of the hierarchical level.

In further exemplary specific embodiments, it is provided that the method further includes: carrying out 1028 at least one of the following steps based on modified first parameter group GP1′ of an instantaneous hierarchical level or repetition 1026: a) simplifying 102a (FIG. 5) simulation model SM, b) assessing 104 a quality of substitute model EM, c) ascertaining 120 (FIG. 8), for example, identifying, third parameter group GP3, d) expanding 122 substitute model EM based on at least one parameter of third parameter group GP3, e) repeating 124 at least one of the following steps, for example, until a predefinable abort criterion is met: aa) assessing 104 the quality of substitute model EM, bb) ascertaining 120 third parameter group GP3, cc) expanding 122 substitute model EM based on at least one parameter of third parameter group GP3, the predefinable abort criterion including at least one of the following elements: a′) a change of a value of the quality measure GM-EM falls below a predefinable threshold value, b′) a setpoint value for quality measure GM-EM is achieved.

In further exemplary specific embodiments, FIG. 9, it is provided that the method further includes: switching 1030 to a preceding higher hierarchical level and, optionally, repeating 1032 the steps of carrying out 1028 and of switching 1030 to a preceding higher hierarchical level, for example, based on pieces of information or data or results of at least one lower hierarchical level. In further exemplary specific embodiments, this enables an iterative refinement of substitute model EM or of expanded substitute model EM′.

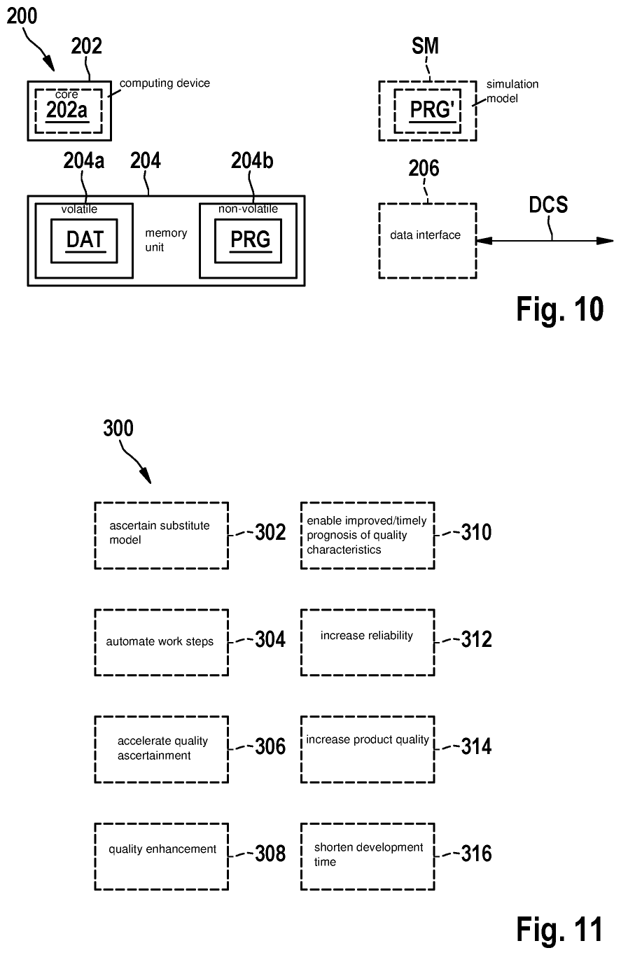

Further exemplary specific embodiments, FIG. 10, relate to a device 200 for carrying out the method according to the specific embodiments. Device 200 includes, for example, a computing device 202 (“computer”) including at least one processor core 202a, a memory unit 204 assigned to computing device 202 for at least temporarily storing at least one of the following elements: a) data DAT (for example, data DAT-SM associated with simulation model SM (FIG. 1), and/or parameters of groups GP1, GP2, GP3), b) computer program PRG, in particular for carrying out a method according to the specific embodiments.

In further preferred specific embodiments, memory unit 204 includes a volatile memory 204a (for example, a working memory (RAM)), and/or a non-volatile memory 204b (for example, a flash EEPROM).

In further exemplary specific embodiments, computing device 202 includes at least one of the following elements, or is designed as at least one of these elements: microprocessor (μP), microcontroller (μC), application-specific integrated circuit (ASIC), system on chip (SoC), programmable logic component (for example, FPGA, field programmable data array), hardware circuitry, graphics processor (GPU), or arbitrary combinations thereof.

Further exemplary specific embodiments relate to a computer-readable memory medium SM, including commands PRG′ which, when executed by a computer 202, prompt the computer to carry out the method according to the specific embodiments.

Further exemplary specific embodiments relate to a computer program PRG, including commands which, when the program is executed by a computer 202, prompt the computer to carry out the method according to the specific embodiments.

Further exemplary specific embodiments relate to a data medium signal DCS, which transmits and/or characterizes computer program PRG, PRG′ according to the specific embodiments. Data medium signal DCS is transmittable, for example, via an optional data interface 206 of device 200.

Further exemplary specific embodiments, FIG. 11, relate to a use 300 of the method according to the specific embodiments and/or of device 200 according to the specific embodiments and/or of computer-readable memory medium SM according to the specific embodiments and/or of computer program PRG, PRG′ according to the specific embodiments and/or of data medium signal DCS according to the specific embodiments for at least one of the following elements: a) ascertaining 302 a substitute model EM for the simulation model SM simplified (for example, including fewer computing resources or less power) compared to simulation model SM, b) automation 304 of work steps for assessing the quality of a or of substitute model EM, c) accelerating 306 a quality ascertainment in simulation models SM, for example, by using substitute model EM, d) quality enhancement 308 of a quality assessment for a substitute model EM, for example, due to an evaluation of substitute model EM in parameter regions not previously considered, e) enabling 310, for example, improved and/or timely prognoses of quality characteristics of a product associated with or corresponding to technical system TS (FIG. 1), f) increasing 312 (FIG. 11) a reliability in a production of a product associated with or corresponding to technical system TS, g) increasing 314 a product quality of a product associated with or corresponding to technical system TS, h) shortening 316 a development time of a product associated with or corresponding to technical system TS.

Exemplary specific embodiments enable at least temporarily an elimination or non-consideration of parameters of simulation model SM less important or irrelevant for a, for example, precise modelling of technical system TS. In this way, for example, the model complexity may be reduced, for example, in connection with a distinction between, for example, stationary and dynamic states, or high-frequency and low-frequency ranges.

Further exemplary embodiments enable at least temporarily a plausibility check by experts, for example, based on few simulation results, to be dispensed with in order to provide a statement about the quality of the results of the simulation.

1-21. (canceled)

22. A computer-implemented method for processing data associated with a simulation model, the simulation model being configured to simulate at least one aspect of a technical system, the method comprising:
ascertaining a first parameter group of parameters of the simulation model, whose sensitivity exceeds a predefinable sensitivity limiting value;
ascertaining a substitute model for the simulation model based on the first parameter group; and
assessing a quality of the substitute model to obtain a quality measure characterizing the quality of the substitute model.

23. The method as recited in claim 22, wherein the technical system includes at least one of the following elements: a) hardware, b) software, c) a combination of hardware and software.

24. The method as recited in claim 23, wherein the technical system includes the hardware, and the hardware includes at least one of the following elements: a) a sensor, b) an actuator, c) hardware circuitry, d) an electrical and/or electronic and/or electromechanical component, e) an electric machine, f) a computing device.

25. The method as recited in claim 23, wherein the technical system including the software, and the software includes at least one of the following elements: a) a computer program for operating or for an activation of hardware, b) a computer program for simulating at least one component of the technical system, c) an operating system for a computing device.

26. The method as recited in claim 22, wherein the simulation model is configured for at least one of the following elements: a) computer-implemented simulation of the technical system, b) computer-implemented simulation for researching and/or developing the technical system, c) computer-implemented simulation for discovering errors of the technical system or in the technical system or errors that are related to the technical system caused by the technical system, d) simulation for validating and/or verifying a functional safety of the technical system.

27. The method as recited claim 22, further comprising:
based on the simulation: a) varying at least one parameter which may influence the technical system and/or the simulation mode, and/or b) eliminating errors, and/or c) enabling the technical system.

28. The method as recited in claim 22, further comprising:
carrying out a sensitivity analysis based on a predefinable number of already present simulation evaluations of the simulation model; and
ascertaining the first parameter group based on the sensitivity analysis, the first parameter group including at least one parameter.

29. The method as recited in claim 28, further comprising:
ascertaining a second parameter group of parameters of the simulation model, whose sensitivity does not exceed the predefinable sensitivity limiting value; and
fixing a parameter of the second parameter group at a predefinable value.

30. The method as recited in claim 22, wherein the ascertainment of the substitute model for the simulation model includes:
simplifying the simulation model based on a targeted evaluation of the simulation model via setpoints in a parameter space associated with the first parameter group.

31. The method as recited in claim 22, wherein the assessment of the quality of the substitute model is carried out based on one or on a predefinable number of already present simulation evaluations of the simulation model.

32. The method as recited in claim 22, further comprising:
ascertaining a third parameter group whose parameters influence a quality of the assessment of the quality of the substitute model; and
expanding the substitute model based on at least one parameter of the third parameter group based on at least one evaluation of the simulation model for the at least one parameter of the third parameter group.

33. The method as recited in claim 32, further comprising:
repeating at least one of the following steps until a predefinable abort criterion is met: a) assessing the quality of the substitute model, b) ascertaining the third parameter group, c) expanding the substitute model based on at least one parameter of the third parameter group, and wherein the predefinable abort criterion includes at least one of the following elements: a) a change of a value of the quality measure falls below a predefinable threshold value, b) a setpoint value for the quality measure is achieved.

34. The method as recited in claim 22, wherein at least some of the steps are automated and are carried out without interaction with a person.

35. The method as recited in claim 33, wherein the ascertainment of the substitute model for the simulation model includes: at least temporarily storing parameters of the first parameter group and assigning to a hierarchical level of a first hierarchical level, carrying out a sensitivity analysis based on the first parameter group, ascertaining a modified first parameter group based on the sensitivity analysis, the modified first parameter group corresponding to a second hierarchical level, and repeating the steps of the at least temporary storing, of carrying out the sensitivity analysis based on the first parameter group, and of ascertaining the modified first parameter group, incrementing the hierarchical level, until a predefinable abort criterion is met, the predefinable abort criterion including a predefinable number of repetitions corresponding to an instantaneous value of the hierarchical level.

36. The method as recited in claim 35, further comprising: carrying out at least one of the following steps based on the modified first parameter group of an instantaneous hierarchical level or repetition: a) simplifying the simulation model, b) assessing a quality of the substitute model, c) ascertaining the third parameter group, d) expanding the substitute model based on at least one parameter of the third parameter group, e) repeating at least one of the following steps until a predefinable abort criterion is met: aa) assessing the quality of the substitute model, bb) ascertaining the third parameter group, cc) expanding the substitute model based on at least one parameter of the third parameter group, and wherein the predefinable abort criterion includes at least one of the following elements: a′) a change of a value of the quality measure falls below a predefinable threshold value, b′) a setpoint value for the quality measure is achieved.

37. The method as recited in claim 36, further comprising: switching to a preceding higher hierarchical level and, repeating the step of carrying out the switching to a preceding higher hierarchical level based on pieces of information or data or results of at least one lower hierarchical level.

38. A device configured to process data associated with a simulation model, the simulation model being configured to simulate at least one aspect of a technical system, the device configured to:
ascertain a first parameter group of parameters of the simulation model, whose sensitivity exceeds a predefinable sensitivity limiting value;
ascertain a substitute model for the simulation model based on the first parameter group; and
assess a quality of the substitute model to obtain a quality measure characterizing the quality of the substitute model.

39. A non-transitory computer-readable memory medium on which are stored commands for processing data associated with a simulation model, the simulation model being configured to simulate at least one aspect of a technical system, the commands, when executed by a computer, causing the computer to perform the following steps:
ascertaining a first parameter group of parameters of the simulation model, whose sensitivity exceeds a predefinable sensitivity limiting value;
ascertaining a substitute model for the simulation model based on the first parameter group; and
assessing a quality of the substitute model to obtain a quality measure characterizing the quality of the substitute model.

40. The method as recited in claim 22, further comprising using the method for at least one of the following elements: a) ascertaining a substitute model for the simulation model simplified as compared to the simulation model, b) automating work steps for assessing the quality of the substitute model, c) accelerating a quality ascertainment in simulation models by using the substitute model, d) quality enhancement of a quality assessment for a substitute model based on an evaluation of the substitute model in parameter regions not previously considered, e) enabling improved and/or timely prognoses of quality characteristics of a product associated with or corresponding to the technical system, f) increasing a reliability in a production of a product associated with or corresponding to the technical system, g) increasing a product quality of a product associated with or corresponding to a technical system, h) shortening a development time of a product associated with or corresponding to the technical system.
